(19) United States
(12) Patent Application Publication
(10) Pub. No.: US 2005/0237051 A1
(43) Pub. Date: Oct. 27, 2005

(54) Optical current sensor with flux concentrator and method of attachment for non-circular conductors

(75) Inventors: Paul Grems Duncan, Vienna, VA (US); John Alan Schroeder, Leesburg, VA (US); Kee P. Koo, McLean, VA (US); Robert Becker, Centreville, VA (US); Benjamin Feldman, Reston, VA (US); Scott Tilton, Leesburg, VA (US); Paul Howard, McLean, VA (US)

Correspondence Address: GREENBERG-TRAURIG, 1750 TYSONS BOULEVARD, 12TH FLOOR, MCLEAN, VA, 22102, US

(73) Assignee: Airak, Inc., Ashburn, VA (US)

(21) Appl. No.: 11/073,378

(22) Filed: Mar. 7, 2005

Related U.S. Application Data
(60) Provisional application No. 60/550,079, filed on Mar. 5, 2004.

(51) Int. Cl. G01R 33/00; G01R 1/00

(52) U.S. Cl. 324/126

(57) ABSTRACT

An optical sensor and sensor housing for measuring the magnitude and phase of an electrical current flowing through a conductor. Also disclosed is a flux concentrator method for rejecting external influences of adjacent conductors, as well as a method for attaching said sensor and flux concentrator to non-circular conductors.

This application is related to U.S. patent application Ser. No. 10/294,905, filed Nov. 15, 2002, and claims the benefit of Provisional U.S. Patent Application Ser. No. 60/550,079, which are hereby incorporated by reference in their entirety.

This application includes material that is subject to copyright protection. The copyright owner has no objection to the facsimile reproduction by anyone of the patent disclosure, as it appears in the Patent and Trademark Office files or records, but otherwise reserves all copyright rights whatsoever.

### BACKGROUND OF THE INVENTION

1. Field of the Invention

Disclosed is an optical sensor and sensor housing for measuring the magnitude and phase of an electrical current flowing through a conductor. Also disclosed is a flux concentrator method for rejecting external influences of adjacent conductors, as well as a method for attaching said sensor and flux concentrator to non-circular conductors. Preliminary modeling data relating magnetic performance is disclosed.

It is to be understood that both the foregoing general description and the following detailed description are exemplary and explanatory and are intended to provide further explanation of the invention and the claims filed herewith.

2. Related Art

The need to monitor electrical parameters, specifically current flow through conductors, continues to increase. Drivers of this need include an increasing reliance on stable electricity to power the Nation's growth, the increase in occurrence of adverse interaction between different electrical distribution networks, and unfortunately, an aging infrastructure that in burdened with increased demand but is only able to provide a fixed capacity. Historical methods to monitor electrical parameters rely upon technology that is, at the very least, big and bulky, and at the worst, outdated and limited in its ability to provide the necessary data to correct for abnormal power flow conditions.

Conventional technologies that monitor electrical current flow in switchgear, in transformers, and in overhead wires are typically of a wire-wound toroidal form that encircle the conductor. As the voltage on the conductor increases the size of these current transformers, or “CTs” increases due to voltage insulation and electrical isolation requirements. This fact limits the widespread deployment of CTs, and hence limits those charged with maintaining electrical power flow from having highly reliable, real-time information, especially during abnormal power conditions.

Within the last 20 years a newer technology has immerged that has shown the ability to monitor electrical current flow in conductors, especially those at higher voltages, yet not “grow” in size and weight as the voltage of the monitored system increased. These “optical CTs”, or OCTs, typically surround the conductor that they monitor but because they are connected to the instrumentation via optical fibers, do not have many of the size and insulation limitations of conventional toroidal CTs. Several companies, including ABB, ALSTOM, KVH, and NxtPhase, are offering products based upon this technology.

Classical OCTs suffer from their own set of problems, namely that they are difficult and costly to manufacture, they are heavy, and they typically require that the conductor on which they are mounted be disassembled so that they can be connected. These constraints limit their widespread usage to all but the most critical monitoring locations.

Within the last two years, a newer type of OCT has become available on the market. This OCT does not encircle a conductor but monitors the magnetic field produced by a current carrying conductor at a well-defined point somewhere surrounding the conductor. If the magnitude of the magnetic field is quantified, and if the conductor geometry that produced the magnetic field is known, a highly accurate measurement of the current can be obtained using this point-measurement OCT. An example of a well-known and characterized geometry is a circular conductor—no matter where the point measurement OCT is installed, the magnetic field surrounding a circular conductor is the same for a given distance from the surface of the conductor. This uniformity of the magnetic field greatly simplifies the measurement device, resulting in a sensor that has significantly lower weight, smaller size, and relatively easy signal processing requirements.

This newer OCT, the point-measurement OCT, suffers from interference of adjacent conductors. As a point-measurement device, any magnetic field at the point of measurement will be quantified, whether or not it is the field of interest. This interference is directly related to the distance separating the conductors—the closer the interfering conductors, the higher the error in the desired measurement, and the further apart the conductors, the lower the measurement error. While tolerable in most cases for overhead electrical power lines due to the large separation of conductors, the use of the point measurement OCT within subterranean electrical vaults, or within standard multiple-phase electrical switchgear (breakers, load centers, high power switches, etc.) is largely unacceptable due to the uncertainty in measurement.

U.S. Pat. No. 5,483,161 (1996) to Deeter et al. discloses a magnetic field sensor utilizing high-permeability magnetic flux concentrators with a high-permeability magneto-optic sensing element to increase measurement sensitivity. The sensing element is positioned between two concentrator “tapers”, and the optical energy travels down the center of the concentrator tapers. This embodiment is of the configuration known as an “open-loop” concentrator.

### OBJECTS AND SUMMARY OF THE INVENTION

It is an object of the invention to provide an improved optical sensor for rejecting interference from adjacent conductors.

It is a further object of the invention to provide a method to concentrate the magnetic flux on the sensor element using a geometry that does not require the light path to be coincident with the axis of the flux concentrators.

It is a further object of the invention to provide a method to install the improved sensor in such a manner than the conductor being monitored does not have to be disassembled during installation.

In a preferred embodiment, the invention provides a sensor that uses a rare-earth iron garnet as the sensor element to measure a magnetic field. Light is coupled through the sensor element and a polarimetric change of the light traveling through the sensor element results when it is influenced by an external magnetic field. Two flux concentrators reside on either side of the sensor element at a preferred angle and protrude into a sensor body containing the sensor element and optical fiber. These flux concentrators are connected around the conductor being monitored such that a near closed-loop of flux exists. The amount of external magnetic field present that influences the light path at the sensor element is directly proportional to the angle formed between the centerline defining the two flux concentrator pins and the centerline defining the optical path. The material comprising the flux concentrator also determines the overall amount of external magnetic field present.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of at least one embodiment of the invention.

In the drawings:

FIG. 1 is a perspective view of an optical current sensor embodiment integrated with a closed-loop flux concentrator assembly, which is mounted on a rectangular busbar conductor.

FIG. 2 is a perspective view of a closed-loop flux concentrator assembly and a primary fiber optic sensor pathway.

FIG. 3 is a top view of the flux concentrators and the fiber optic sensor element illustrating a relative angle offset a between the flux concentrator axis and the sensor element axis.

FIG. 4 is a schematic of the sensor assembly illustrating the relative location of flux concentrator taper pins, as well as different labels for internal angles and dimensions.

FIG. 5 is a plot of the angle dependency between the magnetic field vector and the fiber optic sensor lightpath.

### DETAILED DESCRIPTION OF THE PREFERRED EMBODIMENT

Reference will now be made in detail to the preferred embodiments of the present invention, examples of which are illustrated in the accompanying drawings.

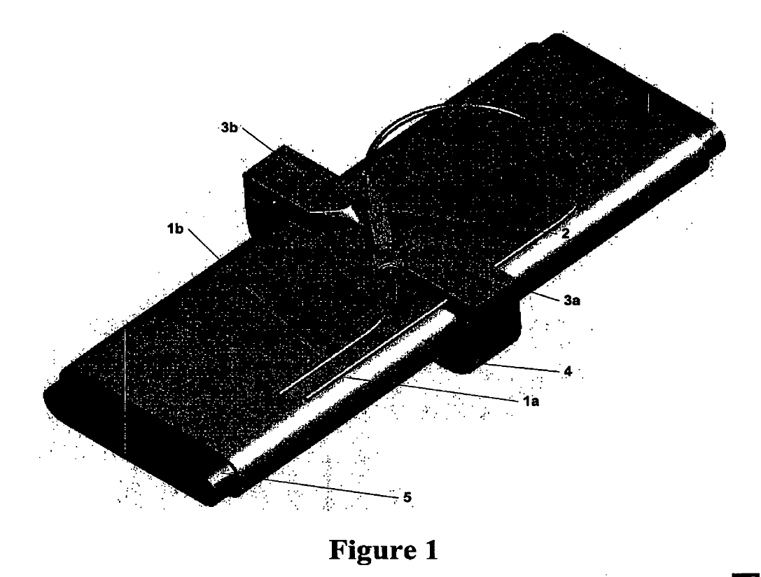

FIG. 1 is a perspective view of an optical current sensor embodiment integrated with a closed-loop flux concentrator assembly, which is mounted on a rectangular busbar conductor 5. The sensor element of the invention is contained in sensor assembly 2, which is preferably manufactured from machinable ceramic or non-ferrous aluminum. The sensor assembly 2 is located between two tapered flux concentrators 3a and 3b, which are preferably made of a ferrous material such as 1018 steel. The tapered flux concentrators 3a and 3b are identical and are symmetrically placed on either side of, and extend into, sensor assembly 2. Optical energy is delivered to and from sensor assembly 2 via optical fibers 1a and 1b, and this optical energy travels axially down the length of sensor assembly 2, where it intersects a sensor element within sensor assembly 2. The flux path around busbar conductor 5 is completed by a “U-shaped” device 4 that connects flux concentrators 3a and 3b.

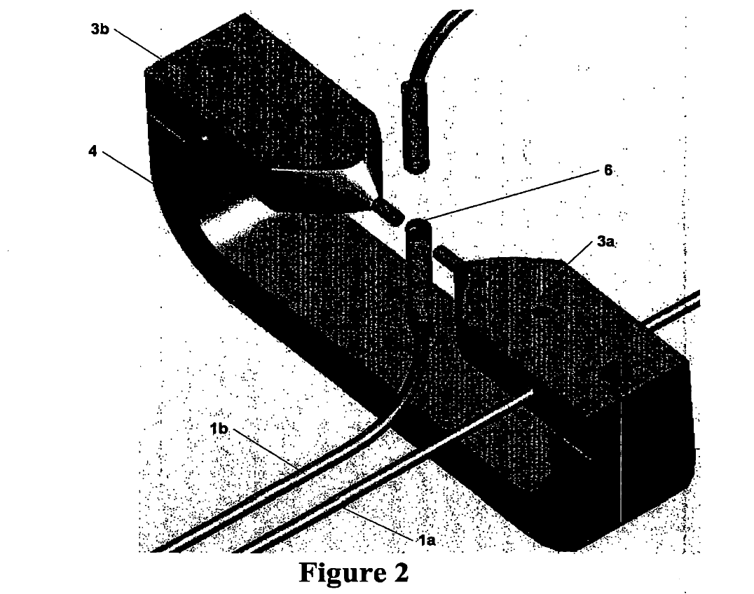

FIG. 2 is a perspective view of the closed-loop flux concentrator assembly and the primary fiber optic sensor pathway. Sensor assembly 2 and busbar conductor 5 of FIG. 1 has been removed, exposing sensor element 6. As illustrated in FIG. 2, light is delivered from optical fiber assemblies 1a and 1b to sensor element 6, which is axially aligned with the optical fibers. Flux concentrators 3a and 3b are preferably rectangular on one end and tapered on the other, so that any flux that resides in the concentrators is focused from the larger surface area into the tapers. Additionally, the “U” concentrator 4 provides a flux pathway from flux concentrator 3a to flux concentrator 3b so that a closed loop is formed around the monitored conductor (FIG. 1 callout 5). Any flux generated from current flow in the conductor will be present in concentrators 3a and 3b and will be focused onto sensor element 6.

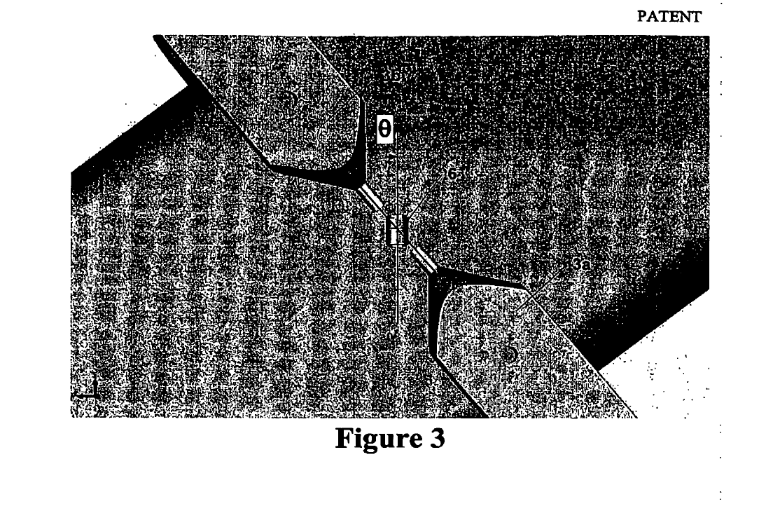

FIG. 3 is a top view of flux concentrators 3a and 3b and fiber optic sensor element 6 showing a relative angle offset θ between the flux concentrator axis and the sensor element axis. This angle, θ, is a function of the flux concentrator 3a and 3b taper pin diameter, the separation between the flux concentrator taper pin endfaces, and the diameter of the sensor element 6. The dependency is due the physical relationship between the magnetic field vector produced by the flux between the taper pin endfaces and the angle of the light traveling through the sensor element 6.

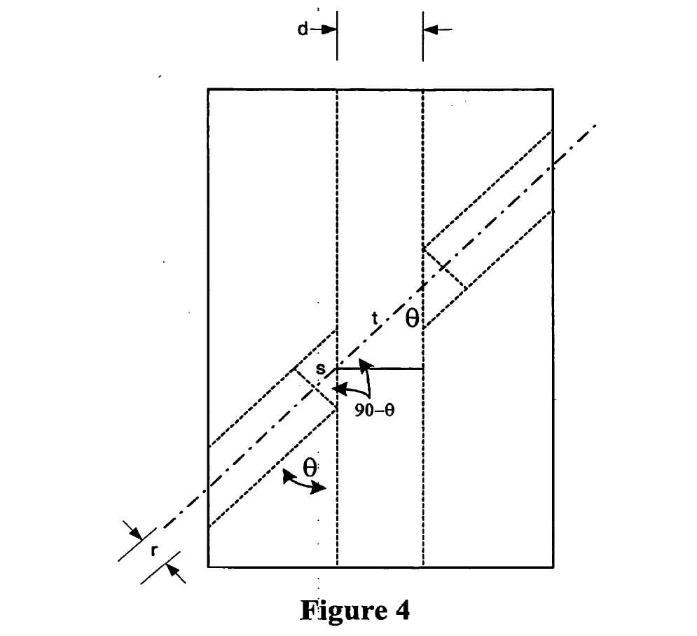

FIG. 4 is a schematic of a preferred sensor assembly illustrating the relative location of the flux concentrator taper pins, as well as different labels for internal angles and dimensions. The sensor element 6 is represented by dimension “d”. The total path length separating the taper pin end faces is given by 2s+t. The flux concentrator taper pins have a radius of “r”. Correspondingly, the total endface separation “L” of the flux concentrator taper pins is given by

$$L := 2 \cdot \frac{r}{tan ( θ )} + \frac{d}{sin ( θ )}$$

The magnetic flux in the gap Φ is a function of the following variables: K, which is related to the electrical current flowing somewhere in the circuit, Ag, the area of the gap, μₒ, the permeability of free space, and L(θ), the distance separating the flux concentrator taper pin endfaces. The expression relating these variables is as follows:

$$ϕ ( θ ) := \frac{K \cdot {μ}_{0} \cdot {A}_{g}}{L ( θ )}$$

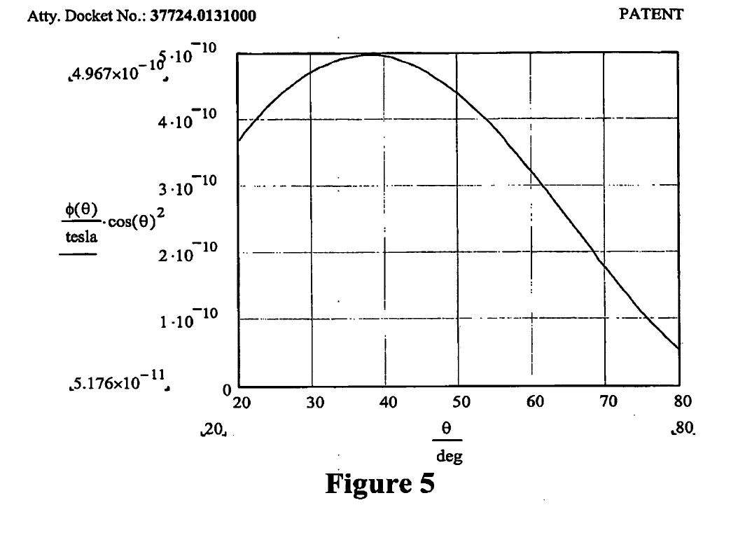

The Faraday effect is a vector-based phenomenon: if the magnetic field vector is orthogonal to the direction of light vector, no measurable magnetic field will be detected. If the magnetic field vector is parallel to the direction of light vector, 100% of the magnetic field present will be measured. The relationship that describes this is given by a form of Malus' Law and is of the cos²θ form, where θ is the angle between the magnetic field vector and the light path vector. Multiplying the above equation for Φ with cos²θ yields the plot shown in FIG. 5.

FIG. 5 clearly shows that a peak occurs for a given magnetic flux field orientation, and given the prior discussion, is a function of the flux concentrator taper radius r and the sensor element 6 diameter d. The angle at which the peak occurs (as read off of the x-axis) is the optimum angle for locating the sensor element 6 within the flux concentrator assemblies 3a and 3b.

The expression relating this peak can be written as:

$$F ( θ ) = \frac{( K \cdot {μ}_{0} \cdot {A}_{g} ) \cdot {cos ( θ )}^{2}}{( 2 \cdot \frac{r}{tan ( θ )} + \frac{d}{sin ( θ )} )}$$

where all the symbols have been previously defined. Differentiating this expression with respect to θ (disregarding terms >O⁶) and setting equal to 0 produces the expression:

$$θ := [ \frac{2}{( 128 \cdot {r}^{2} + 188 \cdot r \cdot d + 122 \cdot {d}^{2} )} \cdot {2}^{\frac{1}{2}} ] \cdot {[ ( 64 \cdot {r}^{2} + 94 \cdot r \cdot d + 61 \cdot {d}^{2} ) \cdot [ \begin{matrix} 66 \cdot r \cdot d - 2 \cdot r \cdot {( 192 \cdot {r}^{2} + 444 \cdot r \cdot d + 75 \cdot {d}^{2} )}^{\frac{1}{2}} … \\ + 21 \cdot {d}^{2} + 48 \cdot {r}^{2} - d \cdot {( 192 \cdot {r}^{2} + 444 \cdot r \cdot d + 75 \cdot {d}^{2} )}^{\frac{1}{2}}\end{matrix} ] ]}^{\frac{1}{2}}$$

If the known values of r and d, as previously defined are substituted into this expression, the optimum angle between the flux concentrator pin axis and the sensor element 6 can be determined to manufacturing tolerance accuracy.

While the invention has been described in detail and with reference to specific embodiments thereof, it will be apparent to those skilled in the art that various changes and modifications can be made therein without departing from the spirit and scope thereof. Thus, it is intended that the present invention cover the modifications and variations of this invention, including equivalents to the appended claims.

1. An electrical current sensor, comprising:
at least one busbar conductor;
a plurality of flux concentrators, wherein each of the plurality of flux concentrators has a first end which is located over the at least one busbar conductor, and wherein each of the plurality flux concentrators is oriented substantially perpendicular to the at least one busbar conductor;
at least one U shaped connector joining the plurality of flux concentrators;
a sensor housing, wherein the sensor housing is located between the first ends of at least two of the plurality of flux concentrators, and wherein the sensor housing has at least first end and a second end;
a sensor, wherein the sensor is located within the sensor housing, and wherein the sensor is oriented at an angle with respect to the flux concentrators;
a first fiber optic cable, wherein the first fiber optic cable is connected to the first end of the sensor housing; and
a second fiber optic cable, wherein the second fiber optic cable is connected to the second end of the sensor housing.

2. The electrical current sensor of claim 1, wherein the sensor is a rare-earth iron garnet.

3. The electrical current sensor of claim 1, wherein the first end of the flux concentrators is substantially circular, with a radius r around a central axis.

4. The electrical current sensor of claim 3, wherein the plurality of flux concentrators is comprised of two flux concentrators.

5. The electrical current sensor of claim 4, wherein the two flux concentrators are oriented such that the first ends of each flux concentrator face each other.

6. The electrical current sensor of claim 5, wherein the two flux concentrators are oriented such that the central axes of the flux concentrators are substantially parallel.

7. The electrical current sensor of claim 6, wherein the sensor has a diameter d.

8. The electrical current sensor of claim 1, wherein the sensor is oriented at an angle, θ wherein
$$θ := [ \frac{2}{( 128 \cdot {r}^{2} + 188 \cdot r \cdot d + 122 \cdot {d}^{2} )} \cdot {2}^{\frac{1}{2}} ] \cdot {[ ( 64 \cdot {r}^{2} + 94 \cdot r \cdot d + 61 \cdot {d}^{2} ) \cdot [ \begin{matrix} 66 \cdot r \cdot d - 2 \cdot r \cdot {( 192 \cdot {r}^{2} + 444 \cdot r \cdot d + 75 \cdot {d}^{2} )}^{\frac{1}{2}} … \\ + 21 \cdot {d}^{2} + 48 \cdot {r}^{2} - d \cdot {( 192 \cdot {r}^{2} + 444 \cdot r \cdot d + 75 \cdot {d}^{2} )}^{\frac{1}{2}}\end{matrix} ] ]}^{\frac{1}{2}}$$

9. The electrical current sensor of claim 1, wherein the sensor housing is comprised of one of machinable ceramic or non-ferrous aluminum.

10. The electrical current sensor of claim 1, wherein the sensor housing is comprised of a combination of machinable ceramic and non-ferrous aluminum.
